(19) United States
(12) Patent Application Publication
(10) Pub. No.: US 2007/0206360 A1
(43) Pub. Date: Sep. 6, 2007

(54) Structure of heat-dispersing protective shell for memory

(76) Inventor: Ying-Hsiu Chu, Yingge Town (TW)

Correspondence Address: RABIN & BERDO, P.C., Suite 500, 1101 14 Street, N.W., Washington, DC, 20005, US

(21) Appl. No.: 11/366,372

(22) Filed: Mar. 3, 2006

(51) Int. Cl. H05K 7/20

(52) U.S. Cl. 361/715

(57) ABSTRACT

A type of structure for a heat dispersing protective shell for memory is comprised of two encasing pieces joined together to protect the whole stick of memory and to help in heat dispersion. The encasing piece is a stamped metal piece moulded to an L shape. The interior of the encasing piece is moulded with a raised area, on which is pasted the adhesive heat dissipater. The upper fringe of the encasing piece is moulded with numerous staggered elevated and sunken buckle pieces that turn upwards. Adjacent elevated and sunken buckle pieces are installed with corresponding grooves and buttons respectively. The two encasing pieces can be quickly installed on the memory, causing the adhesive heat dissipater to stick on the chips of the memory to achieve complete encasing. The manufacturing procedure is quite simple and can greatly increase the heat dispersion and protection of the memory.

### BACKGROUND OF THE INVENTION

I. Field of the Invention

This invention is a “structure of heat dispersion protective shell of memory”. Specifically, it refers to a type of structure of shell used to encase the exterior of the memory for the purpose of heat dispersion and protection.

II. Description of the Prior Art

The mainstream memories used by typical, computers currently are DDRRAM (dual-channel memories). To effectively protect the IC chips on the surface of the memory, and at the same time to effectively lower the temperature of the memory to increase system efficiency and to prevent system crash caused by overheated memory. Many styles of heat dispersion protective clamping apparatuses made of metal materials such as copper or aluminium have emerged on the market. Please refer to FIG. 1, which is formed mainly by two protective pieces a and a buckling apparatus b. The interior of the protective piece a is pasted with elastic adhesive heat spreader a1, and on the exterior surface of the protective piece a is moulded with at least two buckling areas a2 where into the buckling apparatuses b are inserted. The side view of the buckling apparatus b forms a [symbol] n shape and its broadness is slightly smaller than the thickness of the memory c together with the two protective pieces a. After the clamp areas b1 on both flanks of the buckling apparatus b that extend forward have been wedged into the buckling area a2, the two protective pieces a press tightly against the two sides of the memory c. Heat is conducted by the adhesive heat spreader al from the chips to the protective piece a, whereon a big area of metal material is used to achieve the objective of heat dispersion. Besides, the metal protective piece has protection effect and can prevent the chips from damage due to physical impact during the transportation or installation process. However, the foregoing heat dispersion protective clamping apparatus is not only inconvenient to use, it also comprises many components that only increase extra manufacturing costs. Furthermore, when the memory is inserted into the corresponding socket on the computer board for use, the heat dispersion protective clamping apparatus does not entirely seal the top of the memory, the gap thereof from which dust will enter as time goes by. The adhesiveness of the adhesive heat spreader a1 will cause dust to stick to it. Finally, the dust will obstruct the chink between the heat dispersion protective clamping apparatus and the memory, causing ineffective heat dispersion. Therefore, there is a need for further improvement.

Therefore, in view of the foregoing deficiencies of the memory protective clamping apparatus, the inventor, from his meticulous research and accumulation of many years of experience in this field, designs a new type of “structure of heat dispersion protective shell of memory”. Not only is this invention simple to manufacture thus effectively reducing manufacturing costs, it can also be quickly and conveniently installed on memory leading to heat dispersion capability and protection of the encased memory.

### SUMMARY OF THE INVENTION

The main objective of this invention is to provide a type of structure of heat dispersion protective shell that is simple to manufacture and install, which main uses are to encase the memory, improve the heat dispersion capability of the memory, and for protection purpose.

To achieve the foregoing objective, this invention of “structure of heat dispersion protective shell of memory” comprises two encasing pieces joined together. The encasing piece is a stamped metal piece moulded to L shape. The interior of the encasing piece is moulded with raised area, on which is pasted the adhesive heat spreader. The upper fringe of the encasing piece is moulded with numerous staggered elevated and sunken buckle pieces that turn upwards. Adjacent elevated and sunken buckle pieces are installed with corresponding grooves and buttons respectively. The staggered buckle pieces and the piece form an angle slightly smaller than 90 degree.

Based on the foregoing structure, the encasing piece of this invention is made of stamped metal piece which manufacture is quite simple. When using it together with the memory, bring the two encasing pieces on the opposite sides together on the appropriate position on the upper fringe of the memory. Then overlap and buckle the elevated and sunken buckle pieces of the two opposite encasing pieces, causing the adhesive heat spreaders on the interiors of the encasing pieces to stick on the chips of the memory. The chips together with the top of the memory are completely encased by the overlapped and buckled elevated and sunken buckle pieces. This invention is quite convenient and simple to install. Due to the staggered buckle pieces and the piece forming an angle slightly smaller than 90 degree, when the elevated and sunken buckle pieces have been buckled to form a flat surface, the adhesive heat spreaders of the encasing pieces will be forced to move inwards and stick to the memory. Furthermore, the button is completely buckled to the groove and will not fall off. The heat dispersion capability and protection of the memory are greatly increased.

### BRIEF DESCRIPTION OF THE DRAWINGS

FIG. 1 is the three-dimensional analytical diagram of known heat dispersion protective shell.

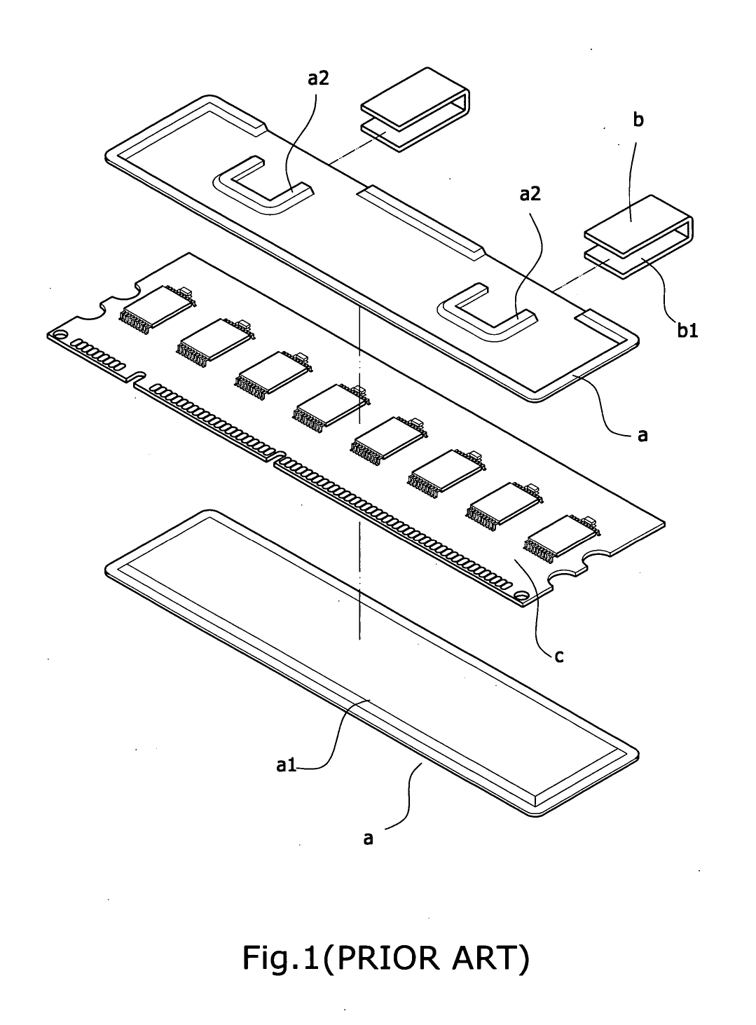

FIG. 2 is the three-dimensional analytical diagram of this invention.

FIG. 3 is the three-dimensional group diagram of this invention.

FIG. 4 is the group cross-sectional diagram of this invention.

FIG. 5 is the three-dimensional analytical diagram of another embodiment of this invention.

FIG. 6 is the group cross-sectional diagram of another embodiment of this invention.

### DESCRIPTION OF THE PREFERRED EMBODIMENT

The structure, installation and features of this invention are explained in detail by a description of the preferred embodiments and figures below.

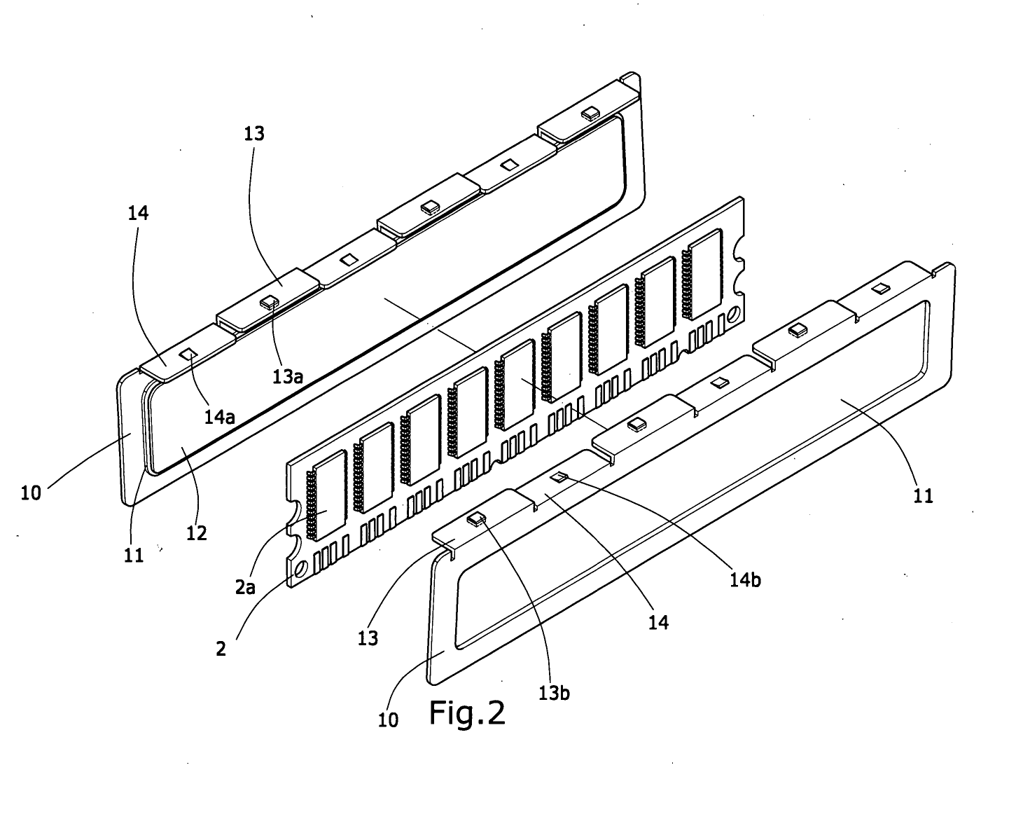

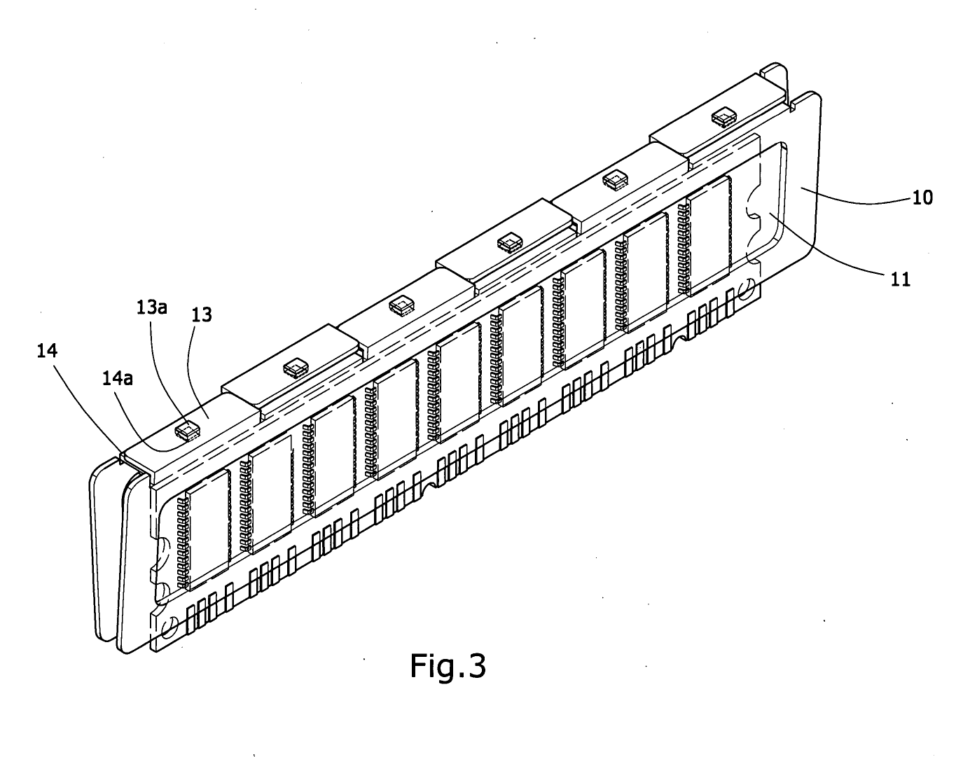

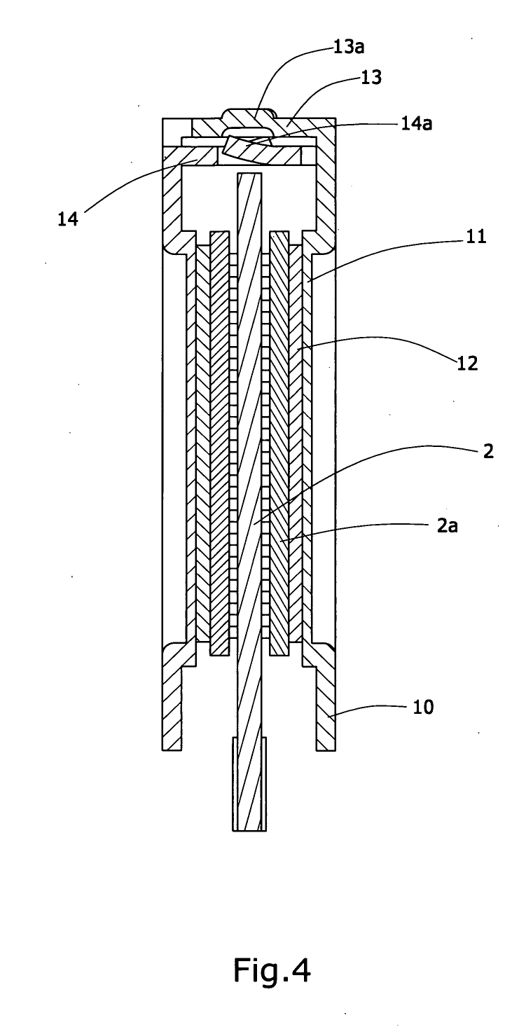

FIGS. 2, 3, and 4 show the “structure of heat dispersion protective shell of memory of this” invention, which comprises two encasing pieces 10 joined together, of which:

The encasing piece 10 is a stamped metal piece moulded to L shape. The interior of the encasing piece 10 is moulded with raised area 11, on which is pasted the adhesive heat spreader 12. The upper fringe of the encasing piece 10 is moulded with numerous staggered elevated and sunken buckle pieces 13 and 14 that turn upwards. The underside of the elevated buckle piece 13 is installed with groove 13a (which could be oblong, round, triangular, etc.), while the top of the corresponding sunken buckle piece 14 is installed with button 14a (which could be oblong, round, triangular, etc.). The staggered buckle pieces 13 and 14 and the piece form an angle slightly smaller than 90 degree.

When installing this assembly, bring the two encasing pieces 10 on the opposite sides together on the appropriate position on the upper fringe of the memory 2. Buckle the groove 13a of the elevated buckle piece 13 to the button 14a of the sunken buckle piece 14 on the two opposite encasing pieces 10. Then the adhesive heat spreaders 12 on the interiors of the encasing pieces 10 stick on the chips 2a of the memory 2. As a result, the desired drop in angle is produced after the elevated and sunken buckle pieces 13 and 14 have been interlocked and buckled. The button 14a will completely buckle to the groove 13a and will not fall off. The memory 2 will be completely encased by the encasing pieces 10.

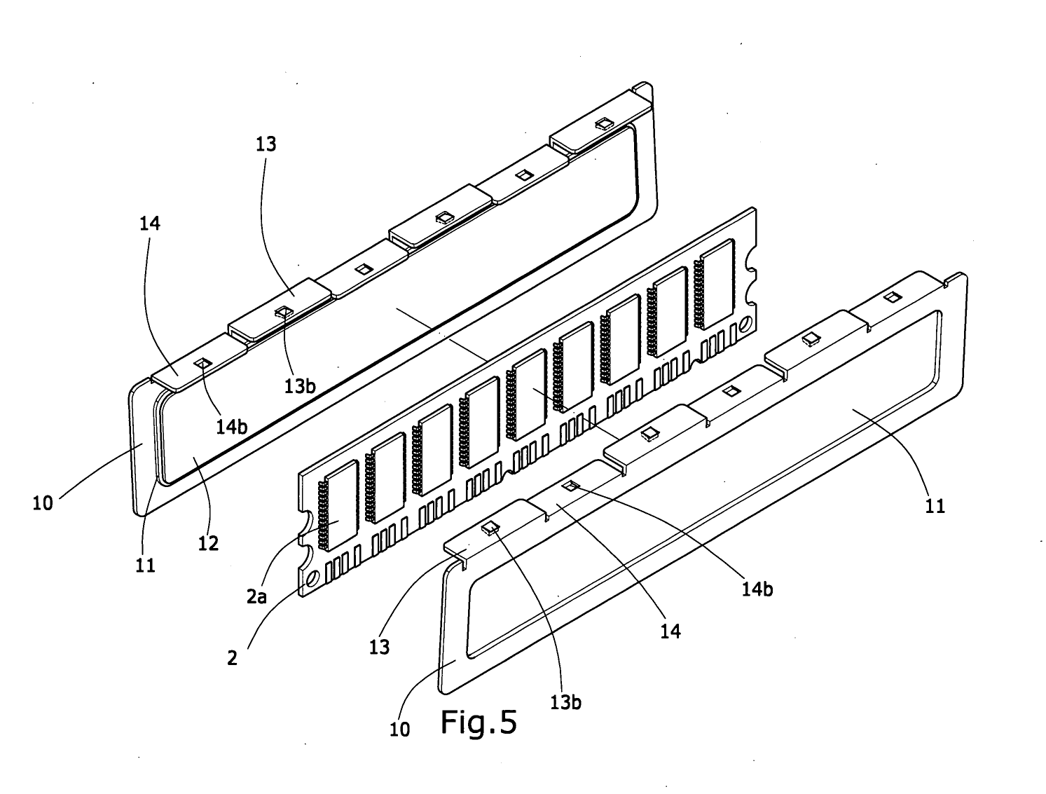

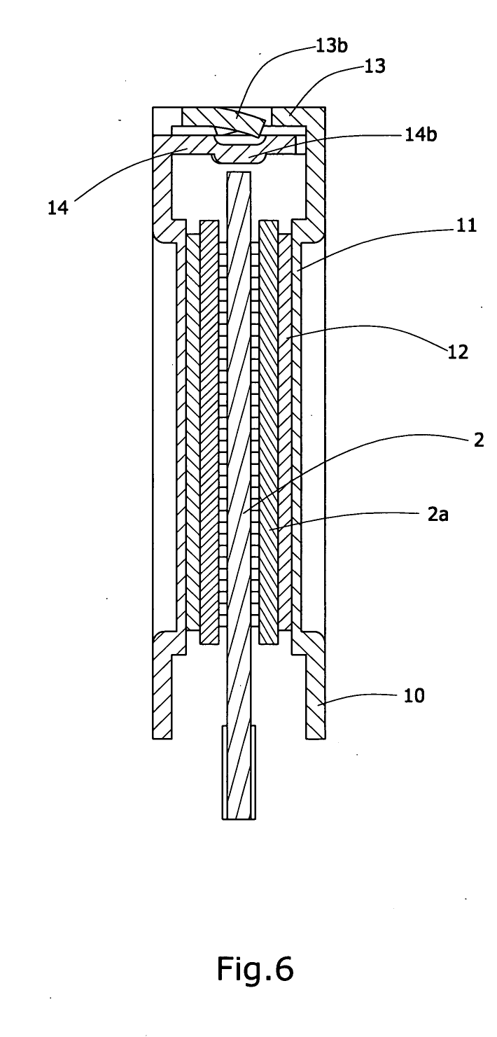

FIGS. 5 and 6 are another embodiment of this invention. The underside of the elevated buckle piece 13 of the encasing piece 10 is installed with button 13b, while the top of the corresponding sunken buckle piece 14 is installed with groove 14b. The installation of the assembly is according to the foregoing steps. Overlap and buckle the two opposite encasing pieces 10 using the buttons 13b of the elevated buckle pieces 13 and the grooves 14b of the sunken buckle pieces 14. Then the adhesive heat spreaders 12 on the interior of the encasing pieces 10 will stick on the chips 2a of the memory 2. As a result, the memory 2 is completely encased by the encasing pieces 10.

To sum up, this invention of “structure of heat dispersion protective shell of memory” uses a shell comprising two encasing pieces to encase the memory. This invention uses simple structure to increase the heat dispersion capability and protection of the memory after it has been encased. Moreover, this invention is “practical” and “advanced”. The applicant hereby submits the patent application for the original solution according to the patent law.

What is claimed is:

1. A type of “structure of heat dispersion protective shell of memory” comprising two encasing pieces joined together to encase and protect the whole stick of memory and to help in heat dispersion, of which the features are as follows. The encasing piece is a stamped metal piece moulded to L shape. The interior of the encasing piece is moulded with raised area, on which is pasted the adhesive heat spreader. The upper fringe of the encasing piece is moulded with numerous staggered elevated and sunken buckle pieces that turn upwards. Adjacent elevated and sunken buckle pieces are installed with corresponding grooves and buttons respectively.

2. The “structure of heat dispersion protective shell of memory” of claim 1, wherein the underside of the elevated buckle piece is installed with groove and the top of the corresponding sunken buckle piece is installed with button.

3. The “structure of heat dispersion protective shell of memory” of claim 1, wherein the underside of the elevated buckle piece is installed with button and the top of the corresponding sunken buckle piece is installed with groove.

4. The “structure of-heat dispersion protective shell of memory” of claim 1, wherein the elevated buckle piece and the piece form an angle slightly smaller than 90 degree.

5. The “structure of heat dispersion protective shell of memory” of claim 1, wherein the sunken buckle piece and the piece form an angle slightly smaller than 90 degree.

6. The “structure of heat dispersion protective shell of memory” of claim 1, wherein the groove is oblong and the corresponding button is also oblong.

7. The “structure of heat dispersion protective shell of memory” of claim 1, wherein the groove is round and the corresponding button is also round.

8. The “structure of heat dispersion protective shell of memory” of claim 1, wherein the groove is triangular and the corresponding button is also triangular.
